(19) United States
(12) Patent Application Publication
(10) Pub. No.: US 2010/0237491 A1
(43) Pub. Date: Sep. 23, 2010

(54) Semiconductor package with reduced internal stress

(76) Inventors: Jin-woo Park, Cheonan-si (KR); Eun-chul Ahn, Yongin-si (KR)

Correspondence Address: LEE & MORSE, P.C., 3141 FAIRVIEW PARK DRIVE, SUITE 500, FALLS CHURCH, VA, 22042, US

(21) Appl. No.: 12/588,852

(22) Filed: Oct. 30, 2009

(30) Foreign Application Priority Data
Mar. 17, 2009 (KR) 10-2009-0022752

(51) Int. Cl. H01L 23/498

(52) U.S. Cl. 257/692; 257/778; 257/738; 257/E23.069

(57) ABSTRACT

A semiconductor package may include a semiconductor chip having a plurality of chip pads arranged apart from each other on a substrate body and an insulation layer having chip pad-exposing portions for exposing chip pads. The insulation layer may be separated by underlying layer-exposing portions between the chip pads, and the semiconductor package may further include a connector in the chip pad-exposing portions and connected to corresponding chip pads.

### BACKGROUND

1. Field

Embodiments relate to a semiconductor package, and more particularly, to a semiconductor package related to reducing internal stress and improving reliability of the package itself and broader level reliability including board level reliability.

2. Description of the Related Art

The electronics industry has been moving toward finding ways to manufacture lighter, smaller, faster, multi-functional, highly efficient, and reliable products at a lower cost. In this regard, one of the most important technologies is semiconductor packaging.

A semiconductor package is generally fabricated by separating a plurality of semiconductor chips formed on a wafer into unitary (individual) semiconductor chips, then forming a bonding wire or a connecting terminal such that the individual semiconductor chips may be connected to a circuit substrate, and protecting the individual semiconductor chips using an encapsulant. A completed semiconductor package may also be used after the semiconductor chips are connected to a main circuit board (or mother board).

Developments in this field of technology have lead to various types of semiconductor packages that may be fabricated. Examples of these semiconductor packages include, but are not limited to, the following: a wafer-level semiconductor package which is fabricated at wafer-level, a chip-size package similar in size to an individual semiconductor chip, and a flip-chip package that may be connected to a main circuit board by flipping a semiconductor chip.

Components housed within a semiconductor package may have different coefficients of thermal expansion, which may cause internal stress during fabrication of the semiconductor package or after fabrication of the semiconductor package. This internal stress may cause deterioration of the reliability of the semiconductor package and/or deterioration of board level reliability, e.g. poor connection when the semiconductor package is connected to a main circuit board.

### SUMMARY

Embodiments are directed to a semiconductor package with reduced internal stress, which substantially overcome one or more of the problems due to the limitations and disadvantages of the related art.

At least one of the above and other features and advantages may be realized by providing a semiconductor package that may include a semiconductor chip having a plurality of chip pads arranged apart from each other on a substrate body, an insulation layer having chip pad-exposing portions for exposing chip pads, and that may be separated by underlying layer-exposing portions between the chip pads, and a connector in the chip pad-exposing portions and connected to the corresponding chip pads. The insulation layer may be separated into discrete portions arranged in a grid pattern by the underlying layer-exposing portions. The underlying layer-exposing portions may expose a passivation layer on the substrate body.

The connector may include a solder ball connecting to a main circuit board. Moreover, the connector may include a bump and a solder ball connected to the bump, for connecting a wiring substrate. Furthermore, the insulation layer may include a photosensitive resin. Moreover, the semiconductor chip may be housed within a wafer fabricated package (WFP) fabricated at wafer level.

The semiconductor package may further include a passivation layer-exposing and insulating the chip pads. Where, the connector may include solder balls connected to corresponding chip pads and at least partially disposed in corresponding chip pad-exposing portions, the solder balls may be separated by the insulation layer.

The semiconductor package may further include a passivation layer-exposing and insulating the chip pads. Where, the connector may include bump pads arranged on corresponding chip pad-exposing portions, that are connected to the corresponding chip pads and separated by the insulation layer, and bumps connected to corresponding bump pads, the bumps being separated by the insulation layer.

The semiconductor package may further include an encapsulant arranged on the top surface and bottom surface of the semiconductor chip to protect the semiconductor chip, the bumps, and the insulation layer, and a wiring substrate connected to first solder balls arranged on corresponding bumps, and a second solder ball may be arranged on the rear surface of the wiring substrate for connecting a main circuit board.

The insulation layer may include a first insulation layer, arranged on the passivation layer and that may expose corresponding chip pads in a first exposing portion, and a second insulation layer, which may expose the chip pads in a second exposing portion on the first insulation layer and exposing the first insulation layer in an insulation exposing portion. Where, the bump pads may be arranged on corresponding chip pads, the first insulation layer, and the second insulation layer. Moreover, the semiconductor chip may be housed in a flip chip package formed by flipping the semiconductor chip, on which the first solder balls may be formed, and attaching the flipped semiconductor chip to a top surface of the wiring substrate.

### BRIEF DESCRIPTION OF THE DRAWINGS

The above and other features and advantages of the present invention will become more apparent to those of ordinary skill in the art by describing in detail exemplary embodiments thereof with reference to the attached drawings, in which:

FIG. 1 illustrates a plan view of a semiconductor package according to an exemplary embodiment;

FIG. 2 illustrates a sectional view of the semiconductor package illustrated in

FIG. 1, taken along a line II-II of FIG. 1;

FIG. 3 illustrates a sectional view of the semiconductor package illustrated in FIG. 1 connected to a main circuit board, according to an exemplary embodiment;

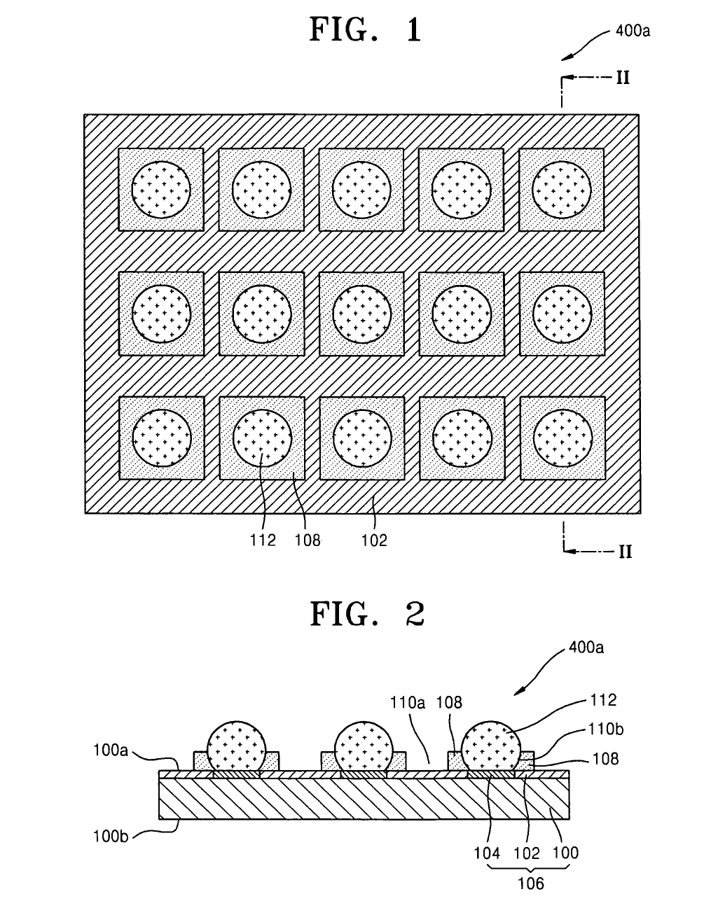

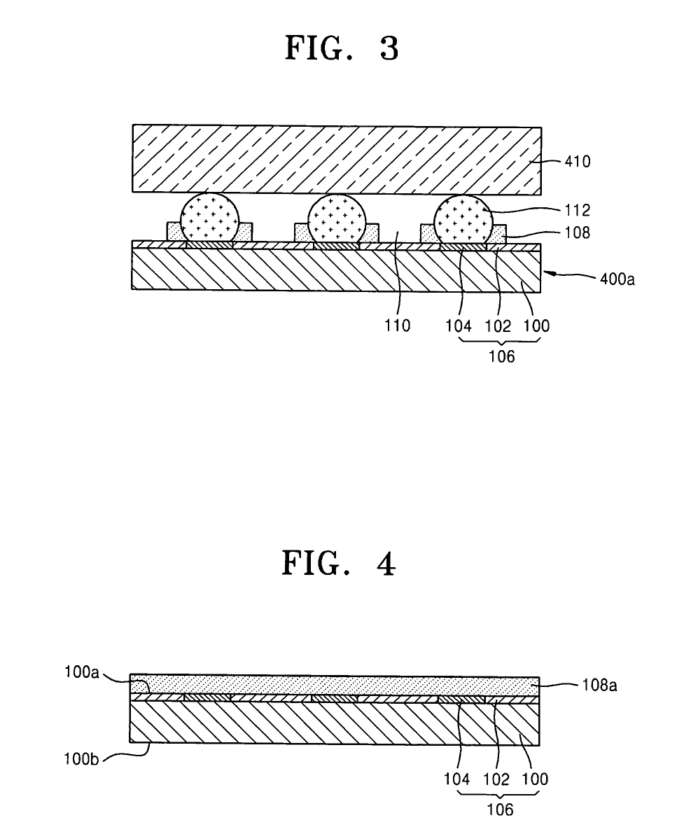

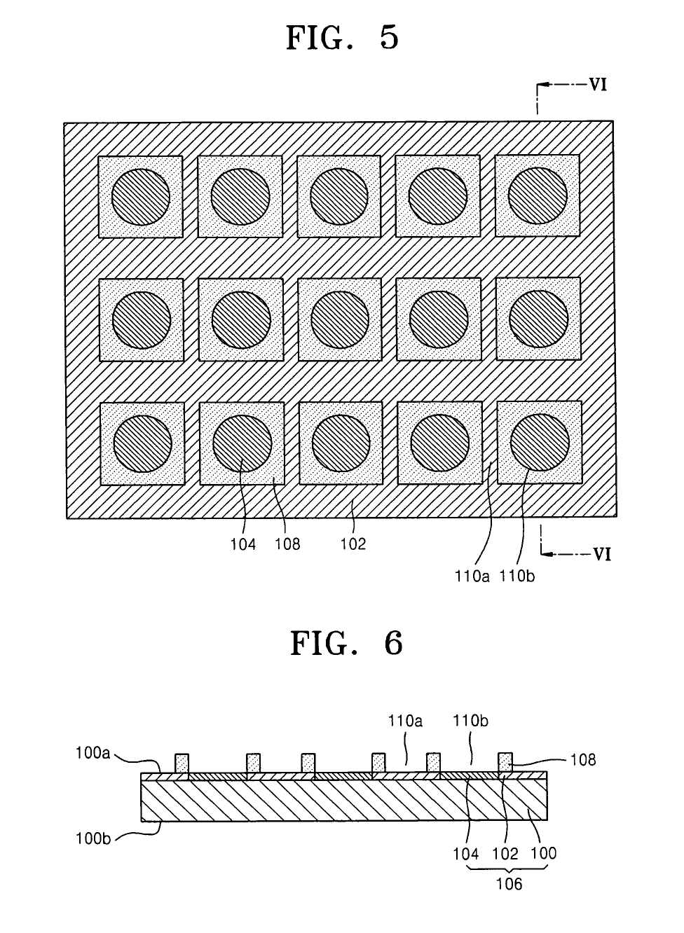

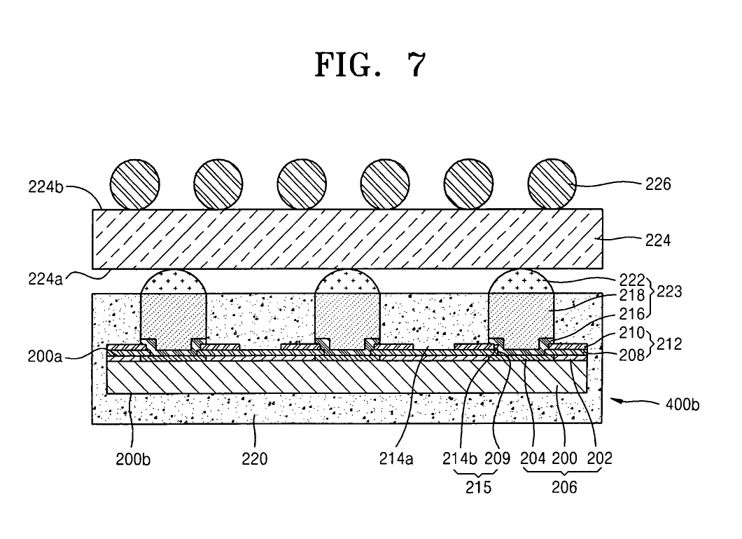

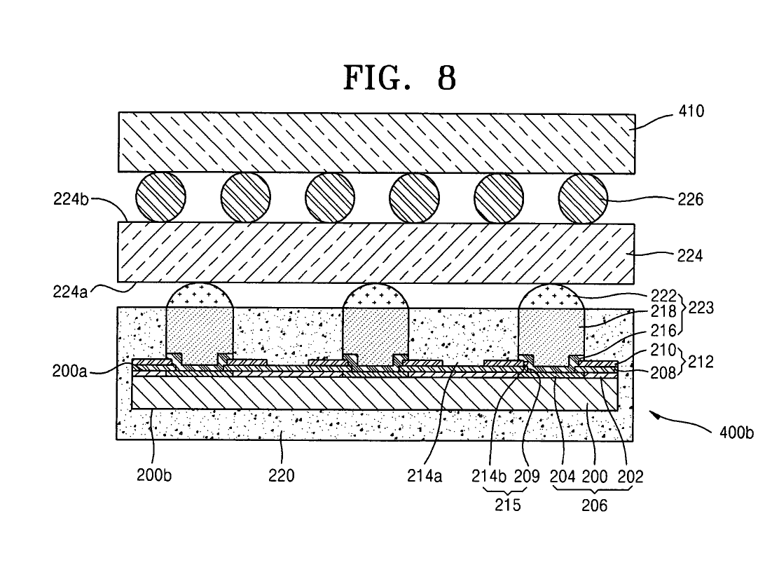

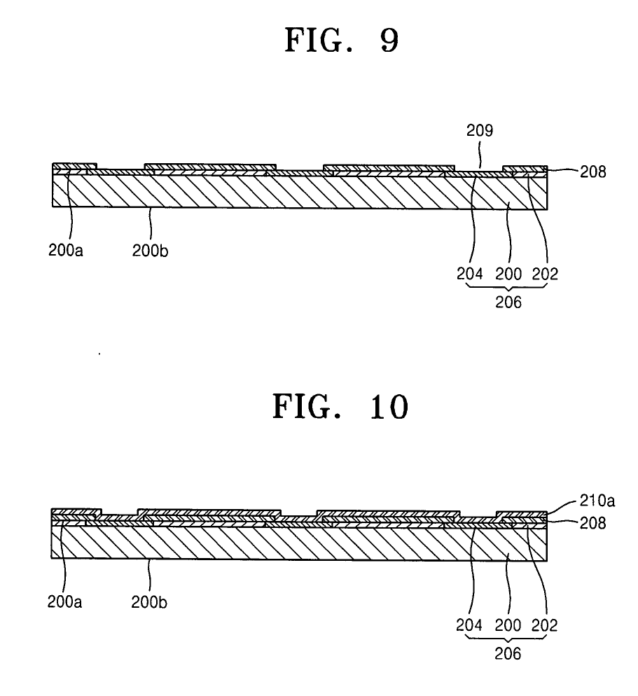

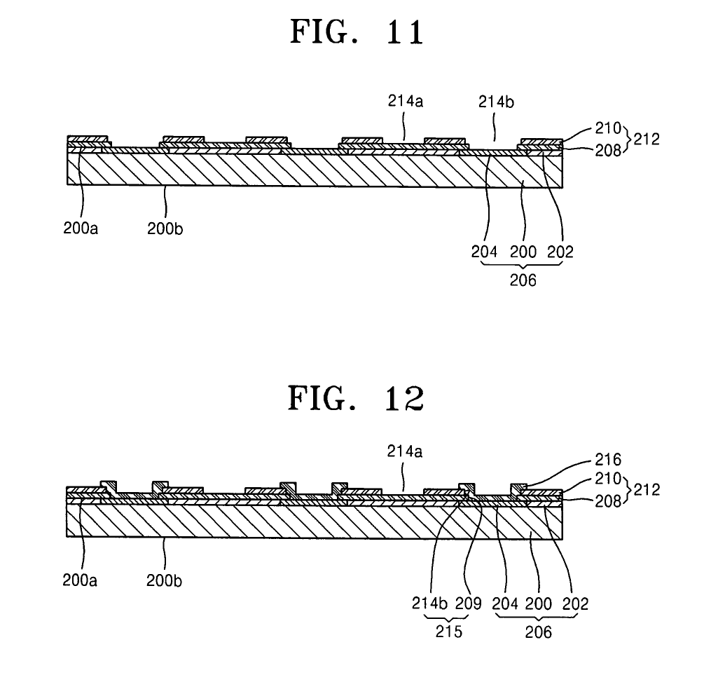

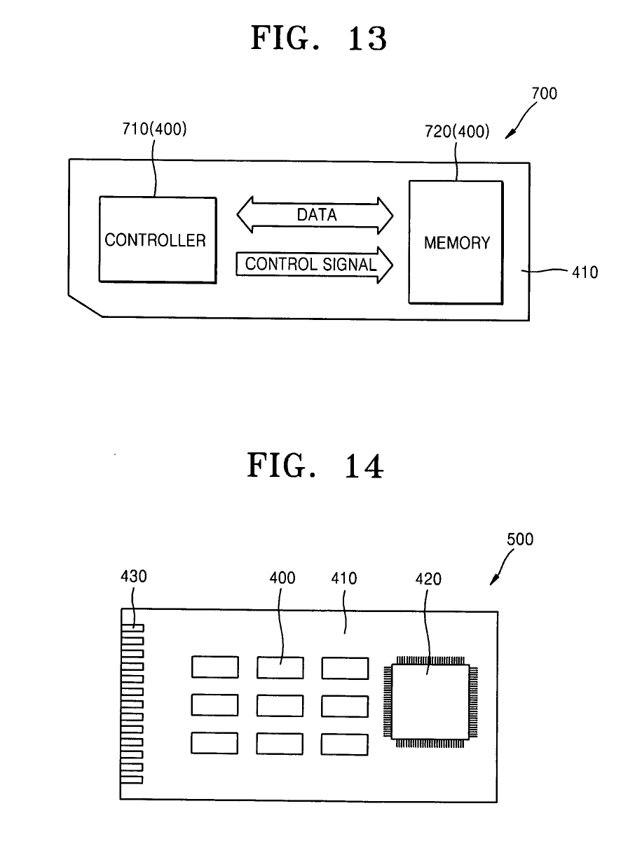

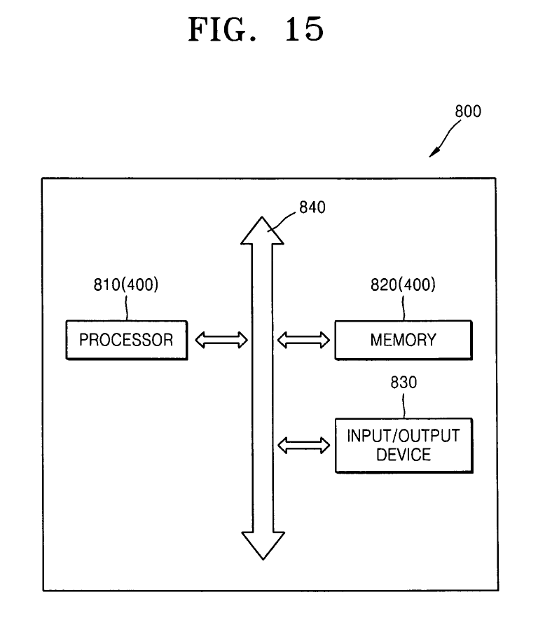

FIGS. 4 through 6 illustrate diagrams for describing methods for fabricating the semiconductor package illustrated in FIGS. 1 and 2;

FIG. 7 illustrates a sectional view of a semiconductor package according to an exemplary embodiment;

FIG. 8 illustrates a sectional view of the semiconductor package illustrated in FIG. 7 connected to a main circuit board 410, according to an exemplary embodiment;

FIGS. 9 through 12 illustrate diagrams for describing methods for fabricating the semiconductor package illustrated in FIGS. 7 and 8;

FIG. 13 illustrates a concept view of a card using a semiconductor package according to an exemplary embodiment;

FIG. 14 illustrates a concept view of a package module using a semiconductor package according to an exemplary embodiment; and

FIG. 15 illustrates a concept view of an electronic system using a semiconductor package according to an exemplary embodiment.

### DETAILED DESCRIPTION

Korean Patent Application No. 10-2009-0022752, filed on Mar. 17, 2009, in the Korean Intellectual Property Office, and entitled: “Semiconductor Package with Reduced Internal Stress,” is incorporated by reference herein in its entirety.

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

A semiconductor package according to the exemplary embodiments discussed herein may include an insulation layer that insulates chip pads on a substrate body that forms a semiconductor chip. Where the insulation layer may be separated into portions that surround each chip pad, and portions of the insulation layer may not be formed in areas between the chip pads.

Further, the semiconductor package according to an exemplary embodiment may further include a connector (e.g. solder balls or bumps) that may be used to connect the semiconductor chip to a circuit board. Moreover, in an exemplary embodiment, portions of the insulation layer may surround each of the connectors, and portions of the insulation layer may not be formed in areas between the chip pads.

As discussed above, according to exemplary embodiments, the insulation layer may be formed spaced apart on the substrate body in the semiconductor package. As such, internal stress, which may occur during or after package fabrication due to different thermal expansion coefficients of each of a plurality of components of the package, may be reduced. Thus, when the semiconductor package is connected to a main circuit board (or mother board) or a wiring substrate, the semiconductor package may exhibit improved reliability of the package itself, may exhibit improved board level reliability, and/or may exhibit improved substrate-level reliability.

Moreover, the semiconductor package may be formed such that an insulation layer is separated into portions that surround each of the chip pads and is formed to reduce internal stress. In other words, the semiconductor package according to an exemplary embodiment may be any type of semiconductor package including an insulation layer for insulating chip pads that is separated into portions that surround each of the individual chip pads.

Embodiments will now be described more fully with reference to the accompanying drawings, in which exemplary embodiments are shown. These exemplary embodiments may, however, be embodied in many different forms and should not be construed as being limited to the embodiments set forth herein. Rather, these embodiments are provided so that this disclosure will be thorough and complete, and will fully convey the concept of the invention to those skilled in the art. In the drawings, the thicknesses of layers and regions are exaggerated for clarity.

FIG. 1 illustrates a plan view of an exemplary embodiment of a semiconductor package 400a. FIG. 2 illustrates a sectional view of the semiconductor package 400a taken along a line II-II of FIG. 1, and FIG. 3 illustrates a sectional view of the semiconductor package 400a connected to a main circuit board 410, according to an exemplary embodiment. The semiconductor package 400a may be a wafer fabricated package (WFP). The WFP type package includes a semiconductor package fabricated at wafer level.

Referring to the exemplary embodiment illustrated in FIG. 2, the semiconductor package 400a may include a semiconductor chip 106. The semiconductor chip 106 may include a top surface 100a, on which a transistor (not shown), circuit pattern (not shown), etc. may be formed. The semiconductor chip 106 may further include a bottom (rear) surface 100b, on which a transistor or a circuit pattern may not be formed. The semiconductor chip 106 may also include a substrate body 100 on which at least one of the following may be formed: a transistor (not shown), a circuit pattern (not shown), a passivation layer 102, and chip pads 104. The passivation layer 102 may be formed on a part of the top surface 100a of the substrate body 100 to protect the transistor, circuit pattern, etc, which may be formed on the top surface 100a. Moreover, the passivation layer 102 may be formed of an insulating type layer, e.g. a nitride film.

Moreover, as shown in FIG. 2, an insulation layer 108 may be formed on the passivation layer 102. The insulation layer 108 may include a chip pad-exposing portion 110b that exposes the underlying chip pads 104 on the substrate 100, and an underlying layer-exposing portion 110a that may expose a layer formed between the chip pads 104. The underlying layer-exposing portion 110a, according to the exemplary embodiment illustrated in FIG. 2, may expose the passivation layer 102.

According to an exemplary embodiment, the chip pads 104 may be formed of an aluminium or copper film. The insulation layer 108 may be formed of photosensitive resin, e.g. polyimide resin.

As shown in FIGS. 1 and 2, the insulation layer 108 may be horizontally separated into portions surrounding each chip pad-exposing portion 110b. Moreover, the underlying layer-exposing portions 110a may also be formed between the chip pads 104. A connector 112, e.g. a solder ball as shown in FIG. 2, may be formed on various chip pads 104 and may be connected to the chip pads 104 on which it is formed. According to an exemplary embodiment, as shown in FIGS. 1 and 2, the connector 112 may be formed on each corresponding chip pad 104. Moreover, the connector 112 may be surrounded by the portions of the insulation layer 108 formed around a corresponding chip pad-exposing portion 110b, and the connectors 112 may be separated by the insulation layer 108.

The semiconductor package 400a, according to an exemplary embodiment, may include the insulation layer 108 having portions surrounding connectors 112 formed on the top surface 100a of the semiconductor chip 106. These portions of the insulation layer 108 may be formed around each of the connectors 112 and each portion may be separated between each connector 112 in order to protect the semiconductor chip 106. The separated insulation layer 108 in the semiconductor package 400a may reduce the internal stress due to different thermal expansion coefficients of components of the semiconductor chip 106.

In other words, referring to the exemplary embodiment shown in FIGS. 1 and 2, since the semiconductor package 400a may include the separated insulation layer 108 between chip pads 104, internal stress due to different thermal expansion coefficients of the substrate body 100 that may include the transistor, circuit pattern, etc., the passivation layer 102, the chip pads 104, and the connector 112 may be reduced. Accordingly, if internal stress of the semiconductor chip 106 is reduced, reliability of the package itself and/or board level reliability when the semiconductor chip 400a is connected to a main circuit board 410, as illustrated in FIG. 3, may be improved.

Furthermore, because the separated insulation layer 108 protects the semiconductor chip 106 in the semiconductor package 400a, according to an exemplary embodiment, a molding operation employed in general packaging methods is not required. Thus, the overall semiconductor package fabrication process can be simplified. In other words, a process of fabricating a semiconductor package can be simplified because a molding operation using epoxy resin or the like for protecting the semiconductor chip 106 is not required.

As shown in FIG. 2, the connector 112 may be formed in the chip pad-exposing portion 110b on the chip pads 104. As shown in FIG. 3, the connector 112 may also be a connecting terminal for connecting the semiconductor package 400a to an external main circuit board 410. FIG. 3 also illustrates that the connector 112 may be a solder ball. Thus, the connector 112 may be formed on the chip pads 104 of the semiconductor chip 106, and the separated insulation layer 108 may be formed between chip pads 104.

FIGS. 4 through 6 illustrate diagrams for describing exemplary steps related to fabricating the semiconductor package 400a illustrated in FIG. 2. More specifically, FIGS. 4 and 6 illustrate sectional views for an exemplary method of fabricating the semiconductor package 400a with respect to the line II-II of FIG. 1, and FIG. 5 is a plan view of FIG. 6.

Referring to FIG. 4, during the process of fabricating the semiconductor package 400a, the semiconductor chip 106 may be formed to include the substrate body 100, which may be formed from a wafer. Moreover, a transistor (not shown), a circuit pattern (not shown), etc, may be formed on the semiconductor chip 106. Also, the semiconductor chip 106 may include the passivation layer 102, and the chip pads 104. Next, a continuous insulation material layer 108a may be formed on the entire top surface 100a of the semiconductor chip 106. In other words, the insulation material layer 108a may be formed on the top surface 100a of the semiconductor chip 106 on which the passivation layer 102 and the chip pads 104 are already formed.

Referring to FIGS. 5 and 6, where FIG. 6 illustrates a sectional view taken along a line VI-VI of FIG. 5, the insulation material layer 108a, shown in FIG. 4, may be patterned using a photolithography method to form the insulation layer 108 shown in FIG. 6. In this regard, the insulation layer 108 may include the chip pad-exposing portion 110b exposing the chip pads 104, and the underlying layer-exposing portion 110a between the chip pads 104. The underlying layer-exposing portions 110a and the chip pad-exposing portions 110b may be simultaneously formed, or they may be formed during separate processing steps. In an exemplary embodiment, as shown in FIGS. 5 and 6, the underlying layer-exposing portions 110a may expose the underlying passivation layer 102 of the semiconductor chip 106. Moreover, the chip pad-exposing portions 110b may expose the chip pads 104 of the semiconductor chip 106.

It may be necessary to form the connector 112 later in the fabrication process, as such, the formation of the chip pad-exposing portion 110b of the insulation layer 108 may be used for connecting the semiconductor chip to a circuit board. Since the underlying layer-exposing portion 110a may also be formed when the chip pad-exposing portion 110b is formed, it may not be necessary to perform an additional operation for forming the underlying layer-exposing portion 110a when the semiconductor package 400a is fabricated.

FIG. 7 illustrates a sectional view of a semiconductor package 400b according to an exemplary embodiment, and FIG. 8 illustrates a sectional view of the semiconductor package 400b connected to a main circuit board 410. Furthermore, the semiconductor package 400b may be a flip chip package type semiconductor package. The flip chip package may be formed by flipping a semiconductor chip 206 and attaching the flipped semiconductor chip 206 to a top surface 224a of a wiring substrate 224.

Referring to FIG. 7, the semiconductor package 400b may include the semiconductor chip 206, and the semiconductor chip 206 may include a top surface 200a on which a transistor (not shown), circuit pattern (not shown), etc. may be formed. The semiconductor chip 206 may further include a bottom (rear) surface 200b, on which a transistor or a circuit pattern may not be formed. The semiconductor chip 206 may also include a substrate body 200, which may have been formed on a wafer, on which the transistor (not shown), the circuit pattern (not shown), etc., a passivation layer 202, and chip pads 204 may be formed. The passivation layer 202 may be formed on the substrate body 200 to protect the transistor, circuit pattern, etc. The passivation layer 202 may be formed of an insulating type layer, e.g. a nitride film.

As shown in FIG. 7, an insulation layer 212, which may include a chip pad-exposing portion 215 exposing the chip pads 204 and an underlying layer-exposing portion 214a between the chip pads 204, may be formed on the passivation layer 202. The insulation layer 212 may be formed of a photosensitive resin such as a polyimide resin. The chip pads 204 may be formed of an aluminium or copper film.

The insulation layer 212 may include a first insulation layer 208, which is formed on the passivation layer 202 and exposes the chip pads 204 in a first exposing portion 209. The insulation layer 212 may further include a second insulation layer 210, which exposes the chip pads 204 in a second exposing portion 214b and exposes a portion of the first insulation layer 208 surrounding the first exposing portion 209. The first exposing portion 209 and the second exposing portion 214b together from a chip exposing portion 215. The insulation layer 212 including the first insulation layer 208 and the second insulation layer 210 may be horizontally separated between the chip pads 204.

Referring to FIG. 7, in an exemplary embodiment, a connector 223 may include a bump pad 216 and a bump 218 that may be formed on the chip pad-exposing portion 215 on the chip pad 204. The bump pad 216 may be formed of a stacked film of a titanium film and a copper film. The bump 218 may have a pillar shape, and may be formed of a copper film. The bump pad 216, which may be connected to the chip pads 204 and may be surrounded by the insulation layer 212, may be formed in the chip pad-exposing portion 215. Furthermore, the bump pads 216 may be formed on the chip pads 204, the first insulation layer 208, and the second insulation layer 210.

The bump 218, which may be connected to the bump pad 216 and may be surrounded by the separated portions of the insulation layer 212 and separated by the insulation layer 212, may be formed on the bump pad 216. In other words, each bump 218, which may be surrounded by the insulation layer 212, may be formed on the bump pads 216 on the chip pads 204 of the semiconductor chip 206. Moreover, the adjacent bumps 218 may be separated by the insulation layer 212. For example, the insulation layer 212 may be separated into portions surrounding the bumps 218 formed on the bump pads 216 on the top surface 200a of the semiconductor chip 206. In other words, the separated insulation layer 212 may be formed in an area between the bumps 218 formed on the bump pads 216 on the top surface 200a of the semiconductor chip 206.

The connector 223 may further include first solder balls 222 that may be formed on corresponding bumps 218. The first solder balls 222 may be attached to the top surface 224a of the wiring substrate 224. The semiconductor package 400b may be connected to the wiring substrate 224 via the first solder ball 222 formed on the bump 218. A second solder ball 226 may be formed on a bottom surface 224b of the wiring substrate 224. The second solder balls 226 may be used to connect the semiconductor package 400b and the writing substrate 224 to other components, e.g. a main circuit board 410 as shown in FIG. 8.

Referring to FIG. 7, according to an exemplary embodiment, an encapsulant 220 may be formed to encapsulate the semiconductor chip 206 in order to protect the semiconductor chip 206, the bump 218, and the insulation layer 212. The encapsulant 220 may be formed to surround the top surface 200a and the bottom surface 200b of the semiconductor chip 206. The first solder ball 222 may be formed on the bump 218 as a part of the connector 223 that extends outside of the encapsulant 220.

The semiconductor package 400b may include the insulation layer 212 separated into portions, where internal stress due to different thermal expansion coefficients of components of the semiconductor chip 206 may be reduced. In other words, the semiconductor package 400b may include the separated insulation layer 212, such that internal stress due to different thermal expansion coefficients of the substrate body 200 including a transistor, circuit pattern, etc., the passivation layer 202, the chip pads 204, and the bumps 218 may be reduced.

In other words, if internal stress of the semiconductor chip 206 is reduced, reliability of the semiconductor package 400b itself, substrate level reliability when a semiconductor chip structure is connected to the wiring substrate 224, and/or board level reliability when the semiconductor package 400b is connected to the main circuit board 410, as illustrated in FIG. 8, may be improved. Furthermore, when the semiconductor package 400b includes the insulation layer 212 separated into portions to reduce internal stress, destruction of the insulation layer 212 may be prevented.

FIGS. 9 through 12 illustrate exemplary methods for fabricating the semiconductor package 400b shown in FIG. 7. Referring to FIG. 9, the semiconductor chip 206 is prepared, and it may include the substrate body 200, which may be formed from a wafer and have formed thereon a transistor (not shown), a circuit pattern (not shown), etc., the passivation layer 202, and the chip pads 204. Next, as shown in FIG. 9, the first insulation layer 208 including the first exposing portion 209, which may expose the chip pads 204, may be formed on the top surface 200a of the semiconductor chip 206. Reference numeral 200b is the bottom surface of the semiconductor chip 206.

Referring to FIG. 10, the second insulation material layer 210a may be formed on the semiconductor chip 206 on which the first insulation layer 208 and the chip pads 204 are already formed. In other words, the second insulation material layer 210a may be formed on the top surfaces of the chip pads 204 and the first insulation layer 208.

Referring to FIG. 11, the second insulation material layer 210a may be patterned using a photolithography method to form the second insulation layer 210. In this regard, as shown in FIG. 11, the second insulation layer 210 may include the underlying layer-exposing portion 214a and the second exposing portion 214b. The insulation exposing portion 214a and the second exposing portion 214b may be formed on the first insulation layer 208 between the chip pads 204 and on the chip pads 204, respectively. The underlying layer-exposing portion 214a may expose the first insulation layer 208 of the semiconductor chip 206, and the second exposing portion 214b may expose the chip pads 204 of the semiconductor chip 206. According to an exemplary embodiment, the underlying layer-exposing portion 214a and the second exposing portion 214b may be formed in the second insulation layer 210 simultaneously.

Referring to FIG. 12, the first exposing portion 209 and the second exposing portion 214b may together form the chip pad-exposing portion 215. The chip pads 204 are surrounded by the insulation layer 212 formed of the first insulation layer 208 and the second insulation layer 210. The chip pads 204 are separated from each other by the insulation layer 212. The portions between the chip pads 204 are separated to each other by the insulation layer 210 having the insulation exposing portion 214a.

It may also be necessary to form the connector 223, that is, the bump pad 216 and the bump 218 later in the fabrication process, as such, the formation of the chip pad-exposing portion 214b may be necessary. Thus, if the underlying layer-exposing portion 214a is formed when the chip pad-exposing portion 214b is formed, it may not necessary to separately perform an additional operation to from the underlying layer-exposing portion 214a when the semiconductor package 400b is fabricated.

Referring to FIG. 12, the bump pads 216, which may be connected to the chip pads 204 and surrounded by the insulation layer 212, may be formed on the chip pads 204. As illustrated in FIG. 7, the bumps 218 may be formed on the bump pads 216 on the chip pads 204. The encapsulant 220 may be formed to encapsulate the semiconductor chip 206 in order to protect the semiconductor chip 206, the bumps 218, and the insulation layer 212. Moreover, the first solder ball 222 may be formed on the bump 218.

According to an exemplary embodiment, the semiconductor chip 206 and the first solder ball 222 may be formed, and then flipped and attached to the top surface 224a of the wiring substrate 224. Furthermore, the second solder ball 226 may be connected to the main circuit board 410, and the second solder ball 226 may be formed on the bottom surface of the wiring substrate 224. At least one of the above may complete an exemplary process of manufacturing the semiconductor package 400b.

Hereinafter, various applications using the semiconductor packages 400a and 400b according to the embodiments will be described. In this regard, there may be many applications, but only a few of them will be described below. Hereinafter, semiconductor packages according to the embodiments will be denoted with the reference numeral 400.

FIG. 13 is a concept view of a card 700 using a semiconductor package 400 according to the inventive concept.

The card 700 may be a multimedia card (MMC), a secure digital (SD) card, or the like. Referring to FIG. 13, the card 700 includes a controller 710 and a memory 720 attached to a main circuit board 410. The memory 720 may be a flash memory, a phase change random access memory (PRAM), or other non-volatile memory. The controller 710 may transmit a control signal to the memory 720, and the controller 710 and the memory 720 may thereby exchange data.

Each of the controller 710 and the memory 720 may be embodied by the semiconductor package 400. In other words, each of the controller 710 and the memory 720 may be constituted by the semiconductor package 400 (400a or 400b), and each with improved package reliability and improved board level reliability may be attached to the main circuit board 410.

FIG. 14 illustrates a concept view of a package module 500 using a semiconductor package 400. Referring to FIG. 14, the package module 500 may include a plurality of the semiconductor packages 400 attached to a main circuit board 410. Thus, the plurality of semiconductor packages 400 with improved board level reliability may be attached to the main circuit board 410. The package module 500 also may include a quad flat package (QFP) type package 420 attached to an end of the package module 500 and a connection terminal 430 attached to the other end of the package module 500. The semiconductor package 400 (400a or 400b) is not limited to application to the package module 500 is shown in FIG. 14, and may be applied to various types of package modules.

FIG. 15 illustrates a concept view of an electronic system 800 using a semiconductor package 400. Referring to FIG. 15, the electronic system 800 may be a computer, a mobile phone, a MPEG Audio Layer-3 (MP3) player, a navigator, or the like. The electronic system 800 may include a processor 810, a memory 820, and an input/output device 830. Control signals or data may be exchanged between the processor 810, the memory 820, and the input/output device 830 via a communication channel 840.

Moreover, the processor 810 and the memory 820 may beach be embodied by the semiconductor package 400 (400a or 400b). In this case, the internal stress of the processor 810 and the memory 820 may be reduced, and reliability of the processor 810 and the memory 820 themselves or board level reliability may be improved when the processor 810 and the memory 820 are connected to a main circuit board (not shown).

Exemplary embodiments have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A semiconductor package, comprising:
a semiconductor chip including a plurality of chip pads arranged apart from each other on a substrate body;
an insulation layer having chip pad-exposing portions for exposing the chip pads, and being separated by underlying layer-exposing portions between the chip pads; and
a connector in the chip pad-exposing portions and connected to corresponding chip pads.

2. The semiconductor package as claimed in claim 1, wherein the insulation layer is separated into discrete portions arranged in a grid pattern by the underlying layer-exposing portions.

3. The semiconductor package as claimed in claim 1, wherein the connector includes a solder ball for connecting to a main circuit board.

4. The semiconductor package as claimed in claim 1, wherein the connector includes a bump and a solder ball connected to the bump, for connecting a wiring substrate.

5. The semiconductor package as claimed in claim 1, wherein the insulation layer includes a photosensitive resin.

6. The semiconductor package as claimed in claim 1, wherein the semiconductor chip is housed within a wafer fabricated package (WFP) fabricated at wafer level.

7. The semiconductor package as claimed in claim 1, wherein the underlying layer-exposing portions expose a passivation layer on the substrate body.

8. The semiconductor package as claimed in claim 1, further comprising a passivation layer-exposing and insulating the chip pads.

9. The semiconductor package as claimed in claim 8, wherein the connector includes:
solder balls connected to corresponding chip pads and at least partially disposed in corresponding chip pad-exposing portions, the solder balls being separated by the insulation layer.

10. The semiconductor package as claimed in claim 9, wherein the insulation layer is separated into discrete portions arranged in a grid pattern by the underlying layer-exposing portions.

11. The semiconductor package as claimed in claim 9, wherein the insulation layer includes a photosensitive resin.

12. The semiconductor package as claimed in claim 9, wherein the semiconductor chip is housed within a wafer fabricated package (WFP) fabricated at wafer level.

13. The semiconductor package as claimed in claim 8, wherein the connector includes:
bump pads arranged on corresponding chip pad-exposing portions, the bump pads being connected to corresponding chip pads and separated by the insulation layer, and
bumps arranged and connected to corresponding bump pads, the bumps being separated by the insulation layer.

14. The semiconductor package as claimed in claim 13, wherein the insulation layer includes:
a first insulation layer arranged on the passivation layer and exposing the chip pads in a first exposing portion; and
a second insulation layer, which exposes the chip pads in a second exposing portion on the first insulation layer and exposes the first insulation layer in an insulation exposing portion.

15. The semiconductor package as claimed in claim 14, wherein the bump pads are arranged on corresponding chip pads, the first insulation layer, and the second insulation layer.

16. The semiconductor package as claimed in claim 13, wherein the semiconductor chip is housed within a flip chip package formed by flipping the semiconductor chip, on which the connector is arranged, and attaching the flipped semiconductor chip to a top surface of a wiring substrate.

17. The semiconductor package as claimed in claim 8, further comprising:
an encapsulant arranged on the top surface and bottom surface of the semiconductor chip to protect the semiconductor chip, the bumps, and the insulation layer;
a wiring substrate connected to first solder balls arranged on corresponding bumps; and
a second solder ball arranged on the rear surface of the wiring substrate for connecting a main circuit board, wherein:
the connector includes:
bump pads arranged on corresponding chip pad-exposing portions, that are connected to corresponding chip pads and separated by the insulation layer, and
bumps arranged and connected to corresponding bump pads, the bump pads being separated by the insulation layer.

18. The semiconductor package as claimed in claim 17, wherein the insulation layer includes:
a first insulation layer arranged on the passivation layer and exposing the chip pads in a first exposing portion; and
a second insulation layer, which exposes the chip pads in a second exposing portion on the first insulation layer and exposes the first insulation layer in an insulation exposing portion.

19. The semiconductor package as claimed in claim 18, wherein the bump pads are arranged on corresponding chip pads, the first insulation layer, and the second insulation layer.

20. The semiconductor package as claimed in claim 17, wherein the semiconductor chip is housed within a flip chip package formed by flipping the semiconductor chip, on which the first solder balls are arranged, and attaching the flipped semiconductor chip to a top surface of the wiring substrate.
